(19) United States
(12) Patent Application Publication
(10) Pub. No.: US 2014/0001440 A1
(43) Pub. Date: Jan. 2, 2014

(54) DIELECTRIC FOR CARBON-BASED NANO-DEVICES

(71) Applicants: Nestor A. BOJARCZUK, Poughkeepsie, NY (US); Matthew W. COPEL, Yorktown Heights, NY (US); Yu-ming LIN, West Harrison, NY (US)

(72) Inventors: Nestor A. BOJARCZUK, Poughkeepsie, NY (US); Matthew W. COPEL, Yorktown Heights, NY (US); Yu-ming LIN, West Harrison, NY (US)

(73) Assignee: International Business Machines Corporation, Armonk, NY (US)

(21) Appl. No.: 13/615,040

(22) Filed: Sep. 13, 2012

Related U.S. Application Data
(63) Continuation of application No. 13/536,875, filed on Jun. 28, 2012.

(51) Int. Cl. H01L 29/78; H01L 21/336; B82Y 99/00; B82Y 40/00

(52) U.S. Cl. 257/27; 438/151; 257/E29.255; 257/E21.409; 977/734

(57) ABSTRACT

A carbon-based semiconductor device includes a substrate, source/drain contacts, a graphene channel, a dielectric layer, and a gate. The source/drain contacts are formed on the substrate. The graphene channel is formed on the substrate connecting the source contact and the drain contact. The dielectric layer is formed on the graphene channel with a molecular beam deposition process. The gate contact is formed over the graphene channel and on the dielectric. The gate contact is in a non-overlapping position with the source and drain contacts leaving exposed sections of the graphene channel between the gate contact and the source and drain contacts.

### CROSS-REFERENCE TO RELATED APPLICATIONS

This application is a continuation of and claims priority from U.S. patent application Ser. No. 13/536,875, Attorney Docket No. YOR920120266US1, filed on Jun. 28, 2012, the entire disclosure of which is herein incorporated by reference.

### STATEMENT REGARDING FEDERALLY SPONSORED RESEARCH OR DEVELOPMENT

This invention was made with Government support under Contract No.: FA8650-08-C-7838 awarded by Defense Advanced Research Projects Agency (DARPA). The Government has certain rights in this invention.

### BACKGROUND

The present invention generally relates to carbon-based devices, and more particularly relates graphene-channel based device and techniques for the fabrication thereof. Graphene is a single layer of graphite. Graphene possesses extraordinary electronic properties. For example, the electron carriers in graphene exhibit very high mobilities that are attractive for high-performance circuits. However, fabrication of a graphene-channel device depends on finding a suitable dielectric. The choice of gate dielectric is crucial in making a graphene-channel device, especially in a top-gated configuration. Graphene's unique electrical properties are a consequence of strong in-plane carbon-carbon bonding. It follows that out-of-plane bonding is suppressed, making subsequent deposition of an insulating layer problematic. Hence, attempts to grow dielectrics on graphene have resorted to unusual measures, such as the use of an organic nucleation layer.

### BRIEF SUMMARY

In one embodiment, a carbon-based semiconductor device is disclosed. The carbon-based semiconductor device comprises a substrate, source/drain contacts, a graphene channel, a dielectric layer, and a gate. The source/drain contacts are formed on the substrate. The graphene channel is formed on the substrate connecting the source contact and the drain contact. The dielectric layer is formed on the graphene channel with a molecular beam deposition process. The gate contact is formed over the graphene channel and on the dielectric. The gate contact is in a non-overlapping position with the source and drain contacts leaving exposed sections of the graphene channel between the gate contact and the source and drain contacts.

In yet another embodiment, a non-transitory tangible computer readable medium encoded with a program for fabricating an integrated circuit structure is disclosed. The program comprising instructions configured to provide a substrate. Source/drain contacts are formed on the substrate. A graphene channel is formed on the substrate connecting the source contact and the drain contact. A dielectric layer is formed on the graphene channel with a molecular beam deposition process. A gate contact is formed over the graphene channel and on the dielectric. The gate contact is in a non-overlapping position with the source and drain contacts leaving exposed sections of the graphene channel between the gate contact and the source and drain contacts.

### BRIEF DESCRIPTION OF THE SEVERAL VIEWS OF THE DRAWINGS

The accompanying figures where like reference numerals refer to identical or functionally similar elements throughout the separate views, and which together with the detailed description below are incorporated in and form part of the specification, serve to further illustrate various embodiments and to explain various principles and advantages all in accordance with the present invention, in which:

FIG. 1 is a chart illustrating the band offsets of various gate dielectrics with respect to graphene;

FIG. 2 is a chart showing the carbon portion of medium energy ion scattering (MEIS) spectra for TiO₂, La₂O₃, and Y₂O₃ overlayers on medium energy ion scattering (HOPG) substrates;

FIG. 3 shows a drain current vs. applied gate voltage chart for various gate dielectrics;

FIG. 4 shows the drain current as a function of drain bias (output characteristics) for various gate dielectrics;

FIG. 5 is a cross-sectional diagram illustrating a graphene layer(s) having been deposited or grown on a substrate according to one embodiment of the present invention;

FIG. 6 is a 3D diagram illustrating a top-down view of the graphene layer(s) having been deposited or grown on substrate according to one embodiment of the present invention;

FIG. 7 is a cross-sectional diagram illustrating a resist mask patterned over the graphene layer(s)/substrate according to one embodiment of the present invention;

FIG. 8 is a 3D diagram illustrating a top-down view of the resist mask patterned over the graphene layer(s)/substrate according to one embodiment of the present invention;

FIG. 9 is a cross-sectional diagram illustrating source/drain contact metal having been deposited around the patterned resist mask according to one embodiment of the present invention;

FIG. 10 is a 3D diagram illustrating a top-down view of the source/drain contact metal having been deposited around the patterned resist mask according to one embodiment of the present invention;

FIG. 11 is a cross-sectional diagram illustrating a mask patterned on the graphene layer(s) to define an active channel region according to one embodiment of the present invention;

FIG. 12 is a 3D diagram illustrating a top-down view of the mask patterned on the graphene layer(s) according to one embodiment of the present invention;

FIG. 13 is a cross-sectional diagram illustrating portions of the graphene layer(s) not protected by the mask having been etched away, and thus defining a graphene channel according to one embodiment of the present invention;

FIG. 14 is a 3D diagram illustrating a top-down view of portions of the graphene layer(s) not protected by the mask having been etched away, and thus defining a graphene channel according to one embodiment of the present invention;

FIG. 15 is a cross-sectional diagram illustrating a gate dielectric having been blanket deposited over the graphene channel, the source and drain metal contacts and the substrate according to one embodiment of the present invention;

FIG. 16 is a 3D diagram illustrating a top-down view of the gate dielectric having been blanket deposited over the graphene channel, the source and drain metal contacts and the substrate according to one embodiment of the present invention;

FIG. 17 is a cross-sectional diagram illustrating a gate metal contact patterned over the graphene channel and separated from the graphene channel by the gate dielectric according to one embodiment of the present invention;

FIG. 18 is a 3D diagram illustrating a top-down view of the gate metal contact patterned over the graphene channel and separated from the graphene channel by the gate dielectric according to one embodiment of the present invention;

FIG. 19 is a cross-sectional diagram illustrating portions of the gate dielectric not covered by the gate metal contact having been etched away according to one embodiment of the present invention;

FIG. 20 is a 3D diagram illustrating a top-down view of the portions of the gate dielectric not covered by the gate metal contact having been etched away according to one embodiment of the present invention;

FIG. 21 is an operational flow diagram illustrating one example of a process for fabricating a carbon-based semiconductor device; and

FIG. 22 is a flow diagram of a design process used in semiconductor design, manufacture, and/or test.

### DETAILED DESCRIPTION

Fabrication of a graphene channel FET requires a graphene (Gr) channel and a gate conductor with an intervening gate dielectric. The gate dielectric needs stop charge from leaking between the gate and the channel, and the dielectric should not contain charge internally. Dielectric (insulating) layers are difficult to deposit on a graphene channel because the carbon atoms in graphene have all their bonds to neighboring carbon atoms. Thus, there are no dangling bonds to nucleate growth of the insulating layer. Methods have been used to overcome this problem, such as use of a metal seed layer to promote growth, or deposition of an organic adhesion layer prior to insulator growth. In the former case, the shortcoming of the seed layer is that metal ions disrupt the graphene lattice, or serve as charged centers for carrier scattering, thus lowering the carrier mobility in graphene channel. Furthermore, it is difficult to insure that the metal seed layer does not migrate and form islands, requiring a careful balancing of oxygen partial pressure during deposition to limit metal mobility. A difficulty associated with the latter case, using organic adhesion layers is that organic insulators are known to contain a high level of trapping defects. Also, the seed layer may limit the capacitance of the device, which is critical in obtaining high performance devices.

Another difficulty in choosing a dielectric concerns the band offsets between graphene and the dielectric. The dielectric needs to be a barrier to tunneling of carriers from the channel to the gate. Thus, both valence band and the conduction band of the dielectric must be several eV from the Dirac point of the graphene. If either the valence or conduction band lies too close to the Dirac point, carriers can easily escape through the dielectric by tunneling. Therefore, one or more embodiments of the present invention provide a reliable and scalable technique to deposit uniform, high-k dielectric layers on graphene without the use of any seed layers, while at the same time inducing minimal impact to the transport in the graphene channel.

In one embodiment, the high-k dielectric layers comprise lanthanum oxide (La₂O₃, and/or lanthanum aluminate (LaAlO₃) and were selected based on experiments performed by the inventors regarding the nucleation of these dielectrics grown by molecular beam deposition (MBD) directly on graphene, and their band offsets. It should be noted that that nucleation is not a sufficient condition for choosing a dielectric, but also the band alignment must create a barrier for electrons and holes. If either the conduction or valence band lies close to the Fermi level, carriers will escape to the gate. A judicious choice of dielectric must not only grow in a continuous film, but must also have a large barrier height to both electrons and holes.

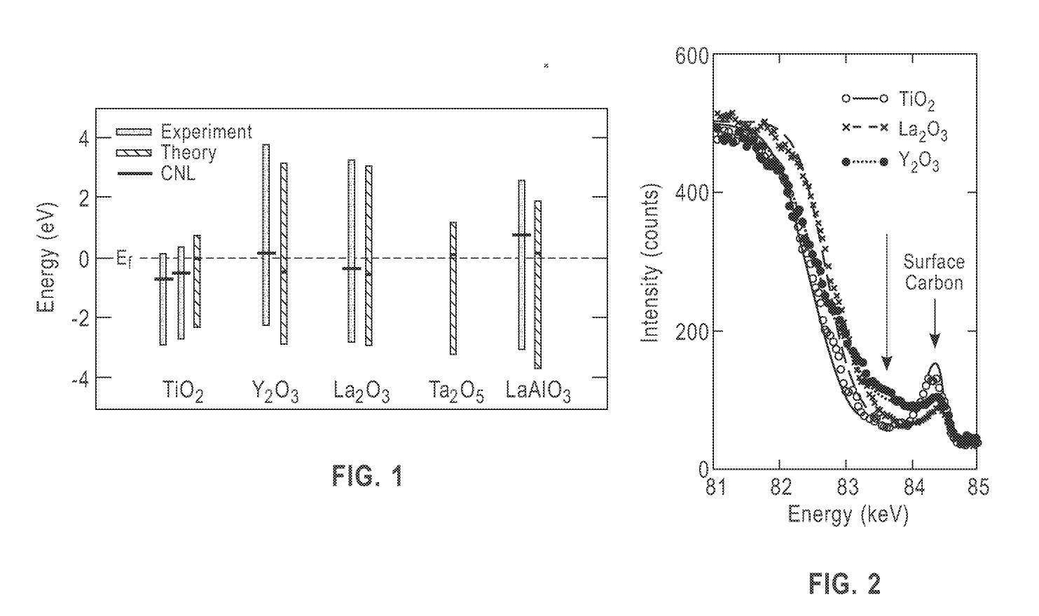

FIG. 1 shows the band offsets of titanium dioxide (TiO₂), tantalum pentoxide (Ta₂O₅), zirconium oxide (Y₂O₃), Y₂O₃, La₂O₃, and LaAlO₃ gate dielectrics with respect to graphene. The theoretical values in FIG. 1 were obtained using MIGS theory, assuming the workfunction of graphene is 4.6 eV. The theoretical framework is described by Robertson in “Papers from the international conference on silicon dielectric interfaces”, Vol. 18 (AVS, Raleigh, N.C. (USA), 2000) p. 1785), which is hereby incorporated by reference in its entirety. The experimental data in FIG. 1 was obtained by x-ray electron spectroscopy of the conduction band edge. It can be seen that insulators such as TiO2 and Ta2O5 have conduction bands that will allow electrons to easily tunnel through the dielectric, whereas La2O3, La2O3, and LaAlO3 are more suitable dielectrics.

Nucleation of the dielectrics was determined experimentally, and depends strongly on the deposition technique. The deposition was performed by evaporation of metals from Knudsen cells. La and Y were evaporated in a background of 1e-4 Ton of molecular O₂. For TiO₂ growth, the oxygen pressure was reduced to 1e-6 Ton. Growth rates were 1 nm/min. With thicknesses of 3 nm to 20 nm. The advantage to using this type of deposition is that the sample can be kept at low temperatures during deposition, hindering the mobility of adsorbed species. This is much different from chemical vapor deposition (CVD) or atomic layer deposition (ALD), where the sample must be heated to activate chemical reactions. In ALD or CVD, there is a thermal barrier to cracking of precursors and desorption of reaction byproducts. No such thermal barrier exists for molecular beam deposition (MBD).

Two methods were used to ascertain whether the insulators formed continuous films: medium energy ion scattering (MEIS) of insulators deposited on highly oriented pyrolytic graphite (HOPG) and scanning electron microscopy (SEM) of insulators on exfoliated graphene. FIG. 2 shows the carbon portion of MEIS spectra of 4 nm thick TiO2, La2O3 and Y2O3 films. Ions backscattered from surface carbon are detected at 84.5 keV, while ions backscattered from carbon deeper in the sample appear at a lower energy. For a continuous film, one would expect the carbon signal to be displaced to lower energy, since the ions lose energy as they traverse the dielectric to encounter the substrate. A discontinuous film would show carbon intensity leading all the way up to the sample surface.

The Y2O3 has a much higher carbon intensity just below the surface (indicated by an arrow). This is a signature of a discontinuous film. The other samples show a valley below the surface channel, where the carbon content dips in the bulk of the dielectric. Quantitative models of the data (smooth curves in FIG. 2) indicate a carbon fraction of 15% in the Y2O3, and 9% in the TiO2 and La2O3. Nucleation of Y2O3 on HOPG is much worse than either TiO2 or La2O3. There is still an appreciable carbon signal in the TiO2 and La2O3 samples, which likely arises from the difficulty in maintaining a pristine HOPG surface during routine handling, rather than carbon incorporated in the dielectric.

SEM images of a 20 nm thickness La2O3 layer deposited at −50 C. on exfoliated graphene showed a uniform film, with little contrast. Cracks or pinholes in the La2O3 would cause contrast in the image. This supports the MEIS finding, that La2O3 forms a uniform layer on graphene. Electrical tests of La2O3 show that the leakage current is below detection threshold, and that the Dirac point can be reached by applying less than 2 volts to the gate electrode. The electrical tests were done on devices with gate widths of 20 microns, and gate lengths of 700 nm. Leakage at 2 volts is less than 2 nA/micron², which was limited by the instrumentation. This is sufficiently low leakage for operation of an FET.

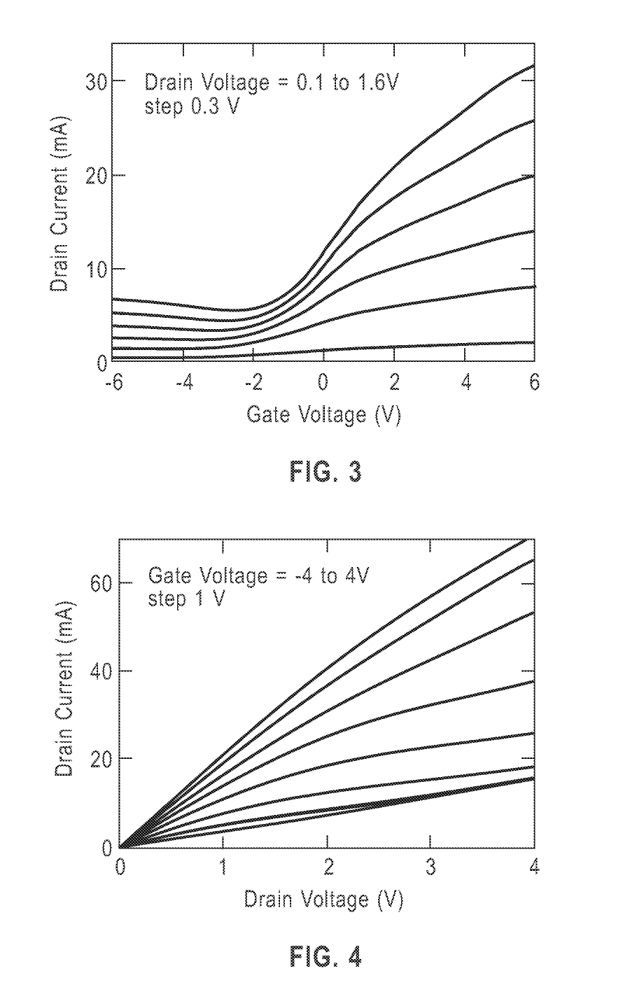

The drain current vs. applied gate voltage shown in FIG. 3 was used to sense the position of the Dirac point. A minimum occurs at the Dirac point, which lies within 2 volts of the origin, indicating little charge in the dielectric. In comparison, it is typical for other dielectrics (e.g. HfO2/NFC/Gr) to find the Dirac point 10-20 volts from the origin. The location of the Dirac point is important for two reasons. First, it is a measure of charge in the dielectric, which can reduce mobility by charge scattering. Second, for operation of a circuit, such as an RF amplifier, the device should be operated at a point where there is a steep change in the drain current with a modulation in the gate voltage. Thus, it is desirable to operate in a region near the Dirac point.

FIG. 4 shows the drain current as a function of drain bias (output characteristics), exhibiting a nice fan-out behavior for various gate voltages. The drain current in the “on” station is over 60 mA for the 20-μm wide devices tested, corresponding to a current density more than 3 mA/um. Such high current density also indicates that the dielectric does not have a significant adverse impact on channel quality. The ability to modulate the current is important to operation of a device as a transistor.

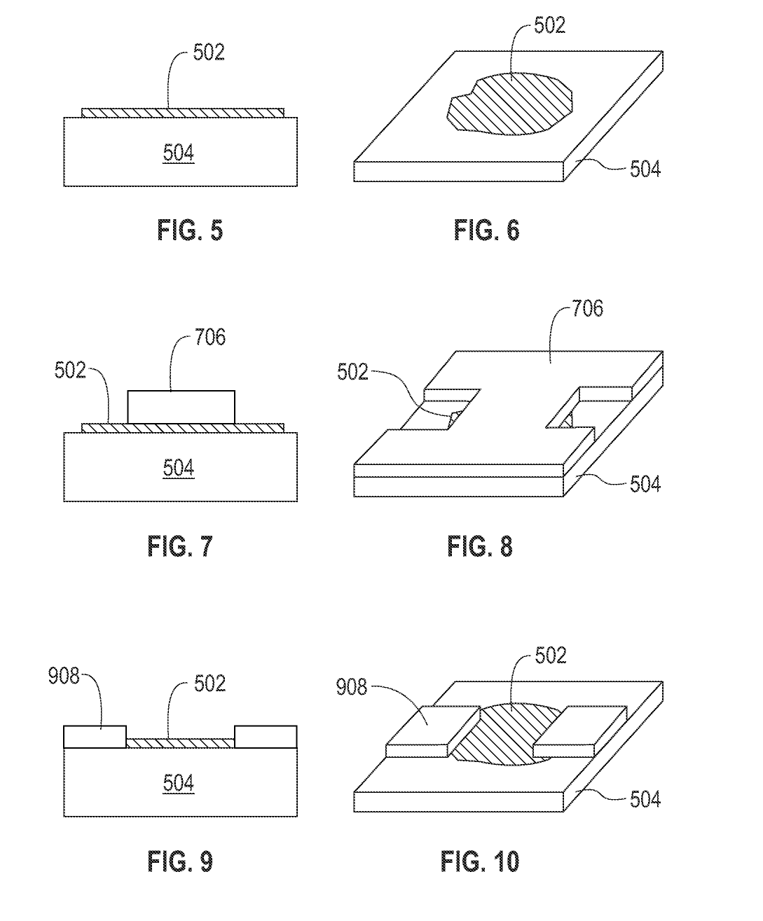

FIGS. 5-20 illustrate various steps of a process for fabricating a graphene-channel nano-device comprising a top-gated FET with a La2O3 or LaAlO3 dielectric. In particular, FIG. 5 is a cross-sectional diagram illustrating one or more graphene layers 502 (e.g., from a single layer up to 10 layers of graphene) having been deposited or grown on a substrate 504. When the graphene layer(s) 502 are deposited, e.g., using mechanical exfoliation, the substrate 504 can be an insulating wafer or a wafer with an insulating overlayer, such as a silicon (Si) wafer covered with silicon dioxide (SiO₂). When the graphene layer(s) 502 are grown, e.g., by silicon sublimation with epitaxy, substrate 504 can be a silicon carbide (SiC) wafer. Techniques for depositing a graphene layer(s) on a substrate that involve, for example, exfoliation and/or techniques for growing a graphene layer(s) on a substrate that involve, for example, SiC epitaxy, are known to those of skill in the art and thus are not described further herein. FIG. 6 is a 3D diagram illustrating another perspective, i.e., a top-down view, of the graphene layer(s) 502 (deposited or grown) on the substrate 504.

The graphene will be configured to serve as an active channel(s) of one or more transistors of the device (also referred to herein as “graphene channel transistors” or simply “graphene transistors”). A resist mask is patterned over the graphene layer(s)/substrate to define the source and drain contact regions. For example, FIG. 7 is a cross-sectional diagram illustrating a resist mask 706 patterned over graphene layer(s) 502/substrate 504. The resist mask 706, in one embodiment, is a soft mask, such as (but not limited to) optical or e-beam lithography resist (PMMA, hydrogen silsesquioxane (HSQ) or S1818™, available from Rohm and Haas Electronic Materials LLC, Marlborough, Mass.) or a hard mask, such as (but not limited to) an oxide, nitride, or metal deposited by a compatible deposition method. Techniques for forming a soft or hard mask are known to those of skill in the art and thus are not described further herein. FIG. 8 is a 3D diagram illustrating another perspective, i.e., a top-down view, of the resist mask 706 patterned over graphene layer(s) 502/substrate 504. From the perspective shown in FIG. 8 it can be seen where the source and drain contact regions are to be formed (as discussed further below).

A contact metal is then deposited. For example, FIG. 9 is a cross-sectional diagram illustrating the source/drain contact metal 908 having been deposited around the patterned resist mask 706. As shown in FIG. 9, once the contact metal 908 has been deposited, the resist mask 706 is removed. The selective metal contact formation follows a standard lift-off process known to those of skill in the art. The metal is first blanket deposited on the resist mask 706/substrate 504 by e-beam evaporation, thermal evaporation or sputtering. Metals such as Pd, Ti, gold (Au), Al, tungsten (W) can be used as the contact metal. After the blanket metal deposition, the resist mask 706 is removed in an appropriate solvent, and by doing so, removing the metal on the resist mask at the same time. According to one embodiment, the resist mask 706 is made of PMMA and can be removed using acetone as the solvent in the lift-off process. FIG. 10 is a 3D diagram illustrating another perspective, i.e., a top-down view, of the source/drain contact metal 908 having been deposited around the patterned resist mask 706.

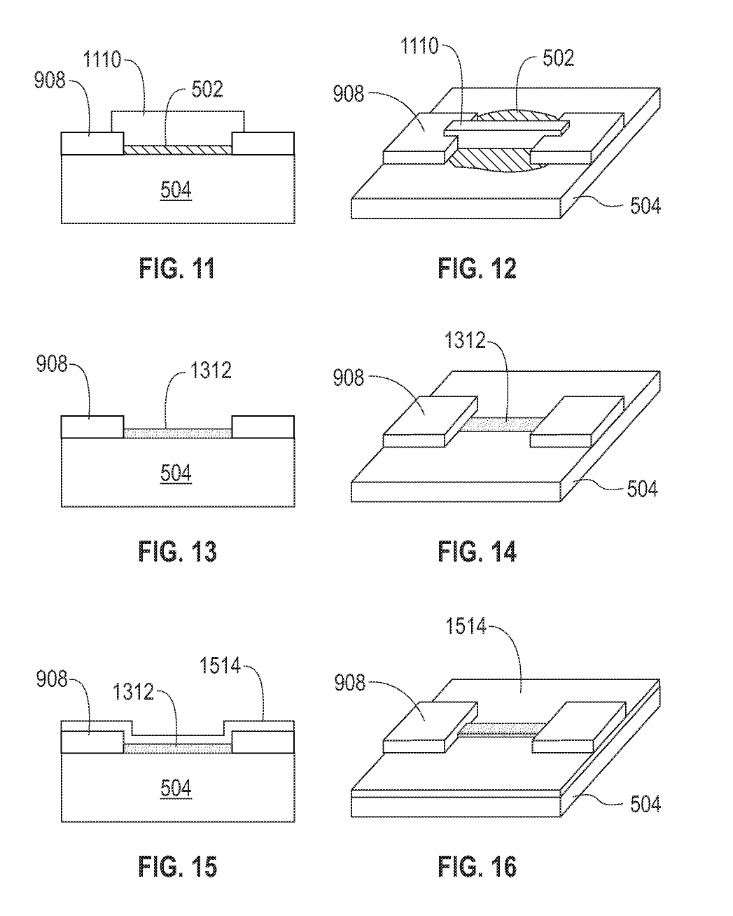

A protective hard or soft mask is then patterned on the graphene to define the active channel region of the device. For example, FIG. 11 is a cross-sectional diagram illustrating mask 1110 patterned on graphene layer(s) 502. Again, the techniques for forming a soft or hard mask are known to those of skill in the art and thus are not described further herein. FIG. 12 is a 3D diagram illustrating another perspective, i.e., a top-down view, of mask 1110 patterned on graphene layer(s) 502.

The unprotected graphene is then removed. For example, FIG. 13 is a cross-sectional diagram illustrating portions of graphene layer(s) 502 not protected by mask 1110 having been etched away, e.g., by dry etching techniques (e.g., O₂ plasma) defining channel 1312 of the device. As shown in FIG. 13, the mask 1110 has also been removed in appropriate solutions. In one embodiment, the etch mask 1110 is made of PMMA and can be removed in acetone. FIG. 14 is a 3D diagram illustrating another perspective, i.e., a top-down view, of portions of graphene sheets 502 not protected by the mask 1110 having been etched away.

After removing the protective mask 1110 to expose the graphene channel 1312, a gate dielectric is deposited on the surface of the device. For example, FIG. 15 is a cross-sectional diagram illustrating gate dielectric 1514 (e.g., an oxide) having been blanket deposited over the device, i.e., over the graphene channel 1312, the source and drain metal contacts 908 and substrate 504. FIG. 16 is a 3D diagram illustrating another perspective, i.e. a top-down view, of the device shown in FIG. 16. In one embodiment, the dielectric 1514 is deposited/grown using molecular beam deposition (MBD) at temperatures at or below room temperature (e.g., ≦20-25° C.), using a metallic source with a flux of molecular oxygen. In this embodiment, the deposition is by evaporation of metals from Knudsen cells. For example, the dielectric 1514, in this embodiment, comprises at least one of La₂O₃ and LaAlO₃. In one embodiment, La is evaporated in a background of 0.5 to 2e-4 Torr with growth rates of 1 nm/min and thicknesses of 3 nm to 20 nm. For example, La₂O₃ and LaAlO₃ films can be made in a Riber 32 chemical beam epitaxy system (CBE). Base pressures prior to all depositions range from 5×10⁻¹⁰Torr to 1×10⁻⁹Torr. Al is deposited from a Riber 135 cc Knudsen cell with a boron nitride crucible, Substrate temperatures can be varied from 300 C. to −42 C. La₂O₃ and LaAlO₃ films can be deposited in the same system, on the same substrates, using the same substrate temperatures as above. However high temperature Vecco Knudsen cells with W and Ta crucibles are used for La deposition. Molecular oxygen (0₂) is introduced into the chamber at a flow of 0.5 to 2 sccm giving a process pressure in the low 1×10-4T range. Deposition rate for is, for example, 0.5 to 1.5 nm/min for La₂O₃, and 1 to 2 nm/min for LaAlO₃.

It should be noted that in another embodiment, that after the source/drain electrode deposition, the dielectric layer 1514 can be formed in a blanket fashion over the entire substrate. To make contact to the underlying electrodes, a resist layer (PMMA or photoresist) is then coated and patterned to expose windows to etch the oxide, either by chemical wet etching or reactive ion etch (RIE).

One advantage of the above dielectric deposition methods is that the sample can be kept at low temperatures during deposition, hindering the mobility of adsorbed species. This is much different from chemical vapor deposition (CVD) or atomic layer deposition (ALD), where the sample must be heated to activate chemical reactions. In ALD or CVD, there is a thermal barrier to cracking of precursors and desorption of reaction byproducts. No such thermal barrier exists for molecular beam deposition (MBD).

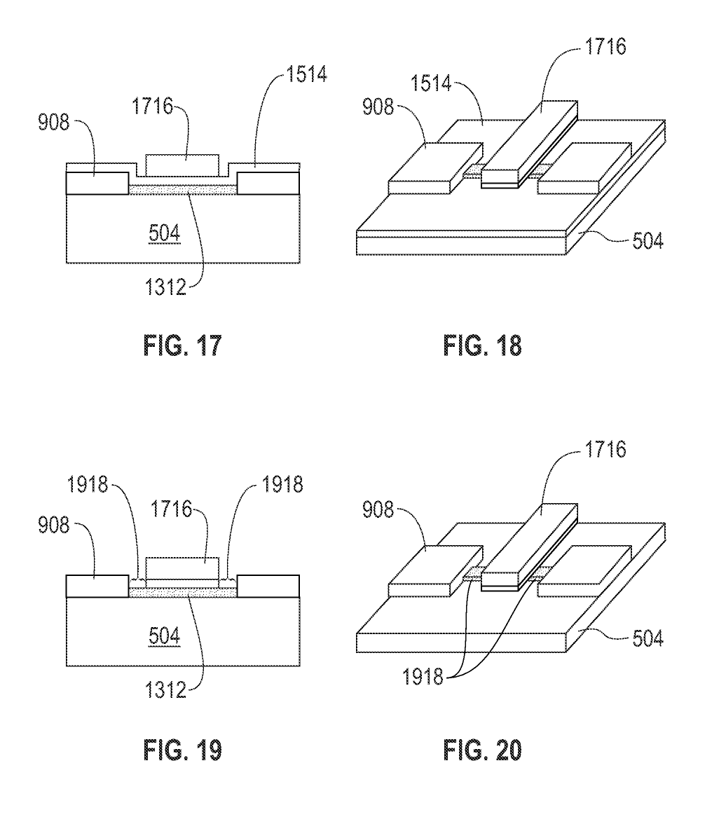

After dielectric deposition, a gate metal contact is patterned on top of the graphene channel. For example, FIG. 17 is a cross-sectional diagram illustrating gate metal contact 1716 patterned over graphene channel 1312 and separated from graphene channel 1312 by gate dielectric 1514. Standard lithographic processes are used in patterning gate metal contact 1716. It is notable from FIG. 17 (and FIG. 18) that gate metal contact 1716 is positioned so as not to extend over (does not overlap) source and drain metal contacts 908. This configuration is also referred to herein as an underlapping gate configuration, i.e., the gate metal contact underlaps the source and drain metal contacts. FIG. 18 is a 3D diagram illustrating another perspective, i.e., a top-down view, of gate metal contact 1716 patterned over the graphene channel 1312 and separated from the graphene channel 1312 by the gate dielectric 1514.

In an optional process the portions of the dielectric that are not covered by the gate metal contact are then etched away. For example, FIG. 19 is a cross-sectional diagram illustrating the portions of gate dielectric 1514 not covered by gate metal contact 1716 having been etched away. This leaves exposed sections 1918 of the graphene channel on either side of gate metal contact 1716. However, it should be noted that the above portions of the dielectric are not required to be etched away. FIG. 20 is a 3D diagram illustrating another perspective, i.e., a top-down view, of the portions of the gate dielectric 1514 that are not covered by the gate metal contact 1716 having been etched away. Optional chemical doping is then performed to dope the exposed sections 1918 of the graphene channel 1312. In this embodiment, an optional dopant can be applied to the device surface, i.e., blanket deposited over source and drain metal contacts 908, gate metal contact 1716, exposed sections 1918 of the graphene channel 1312 and substrate 504. The dopant, in one embodiment, is an n-type (e.g., poly(ethylene imine) (PEI)) or p-type (e.g., diazonium salts) molecular dopant. The sections of the graphene channel 1312 that are exposed to the dopant (i.e., sections 1918) are defined by the position of the gate electrode, resulting in a self-aligned doping/gating structure. In this process the gate metal contact 1716 is used as the etching mask for dielectric removal and the doping mask to define the doping region.

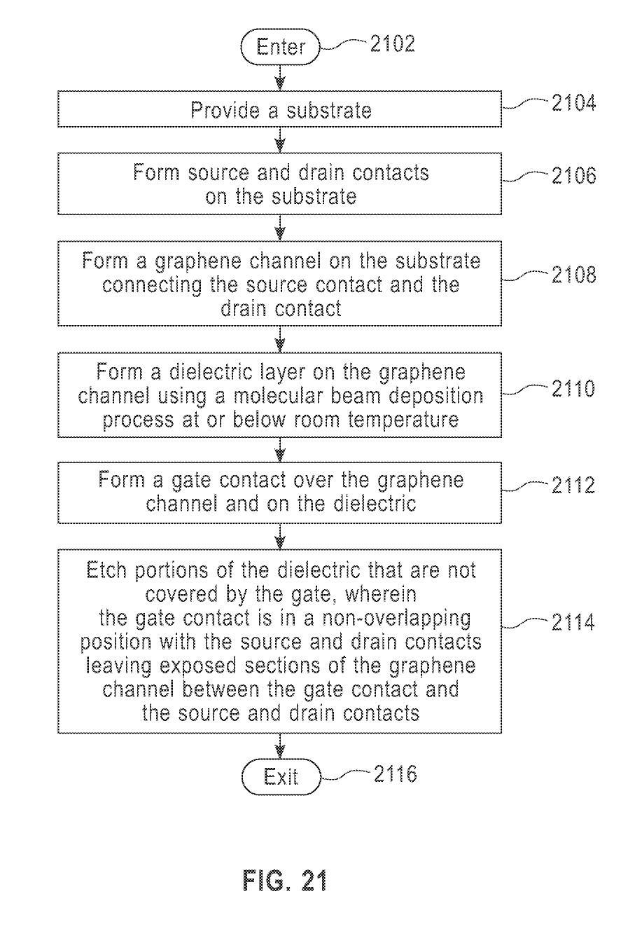

FIG. 21 is an operational flow diagram illustrating a process for fabricating a carbon-based semiconductor device. The operational flow diagram of FIG. 21 begins at step 2502 and flows directly to step 2504. A substrate 502, at step 2104, is provided. Source/drain contacts 908, at step 2106, are formed on the substrate 502. A graphene channel 1312, at step 2108, is formed on the substrate 502 connecting the source/drain contacts 908. A dielectric layer 1514, at step 2110, is formed on the graphene channel 1312 using a molecular beam deposition process. A gate contact 1716, at step 2112, is formed over the graphene channel 1312 and on the dielectric 1514. The portions of the dielectric that are not covered by the gate metal contact, at step 2114, are then optionally etched away. The gate contact 1312 is in a non-overlapping position with the source and drain contacts 908 leaving exposed sections of the graphene channel 1312 between the gate contact 1716 and the source and drain contacts 908. The control flow then exits at step 2116.

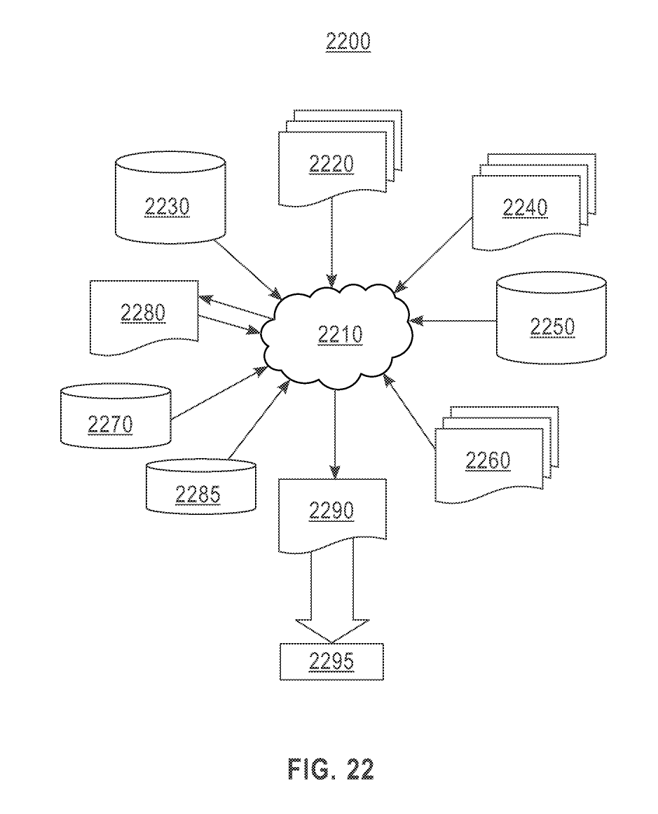

FIG. 22 shows a block diagram of an exemplary design flow 2200 used for example, in semiconductor IC logic design, simulation, test, layout, and manufacture. Design flow 2200 includes processes and mechanisms for processing design structures or devices to generate logically or otherwise functionally equivalent representations of the design structures and/or devices described above and shown in FIGS. 5-20. The design structures processed and/or generated by design flow 2200 may be encoded on computer-readable transmission or storage media to include data and/or instructions that when executed or otherwise processed on a data processing system generate a logically, structurally, mechanically, or otherwise functionally equivalent representation of hardware components, circuits, devices, or systems. Design flow 2200 may vary depending on the type of representation being designed. For example, a design flow 2200 for building an application specific IC (ASIC) may differ from a design flow 2200 for designing a standard component or from a design flow 2200 for instantiating the design into a programmable array, for example a programmable gate array (PGA) or a field programmable gate array (FPGA) offered by Altera® Inc. or Xilinx® Inc.

FIG. 22 illustrates multiple such design structures including an input design structure 2220 that is preferably processed by a design process 2210. Design structure 2220 may be a logical simulation design structure generated and processed by design process 1210 to produce a logically equivalent functional representation of a hardware device. Design structure 2220 may also or alternatively comprise data and/or program instructions that when processed by design process 2210, generate a functional representation of the physical structure of a hardware device. Whether representing functional and/or structural design features, design structure 2220 may be generated using electronic computer-aided design (ECAD) such as implemented by a core developer/designer. When encoded on a machine-readable data transmission, gate array, or storage medium, design structure 2220 may be accessed and processed by one or more hardware and/or software modules within design process 2210 to simulate or otherwise functionally represent an electronic component, circuit, electronic or logic module, apparatus, device, or system such as those shown in FIGS. 5-20. As such, design structure 2220 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 2210 preferably employs and incorporates hardware and/or software modules for synthesizing, translating, or otherwise processing a design/simulation functional equivalent of the components, circuits, devices, or logic structures shown in FIGS. 5-20 to generate a netlist 2280 which may contain design structures such as design structure 1220. Netlist 2280 may comprise, for example, compiled or otherwise processed data structures representing a list of wires, discrete components, logic gates, control circuits, I/O devices, models, etc. that describes the connections to other elements and circuits in an integrated circuit design. Netlist 2280 may be synthesized using an iterative process in which netlist 2280 is resynthesized one or more times depending on design specifications and parameters for the device. As with other design structure types described herein, netlist 2280 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 2210 may include hardware and software modules for processing a variety of input data structure types including netlist 2280. Such data structure types may reside, for example, within library elements 2230 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 2240, characterization data 2250, verification data 2260, design rules 2270, and test data files 2285 which may include input test patterns, output test results, and other testing information. Design process 2210 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 2210 without deviating from the scope and spirit of the invention. Design process 2210 may also include modules for performing standard circuit design processes such as timing analysis, verification, design rule checking, place and route operations, etc.

Design process 2210 employs and incorporates logic and physical design tools such as HDL compilers and simulation model build tools to process design structure 2220 together with some or all of the depicted supporting data structures along with any additional mechanical design or data (if applicable), to generate a second design structure 2290. Design structure 2290 resides on a storage medium or programmable gate array in a data format used for the exchange of data of mechanical devices and structures (e.g., information stored in an IGES, DXF, Parasolid XT, JT, DRG, or any other suitable format for storing or rendering such mechanical design structures). Similar to design structure 2220, design structure 2290 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 5-20. In one embodiment, design structure 2290 may comprise a compiled, executable HDL simulation model that functionally simulates the devices shown in FIGS. 5-20.

Design structure 2290 may also employ a data format used for the exchange of layout data of integrated circuits and/or symbolic data format (e.g., information stored in a GDSII (GDS2), GL1, OASIS, map files, or any other suitable format for storing such design data structures). Design structure 2290 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 5-20. Design structure 2290 may then proceed to a stage 2295 where, for example, design structure 2290: proceeds to tape-out, is released to manufacturing, is released to a mask house, is sent to another design house, is sent back to the customer, etc.

It should be noted that some features of the present invention may be used in one embodiment thereof without use of other features of the present invention. As such, the foregoing description should be considered as merely illustrative of the principles, teachings, examples, and exemplary embodiments of the present invention, and not a limitation thereof.

It should be understood that these embodiments are only examples of the many advantageous uses of the innovative teachings herein. In general, statements made in the specification of the present application do not necessarily limit any of the various claimed inventions. Moreover, some statements may apply to some inventive features but not to others.

The circuit as described above is part of the design for an integrated circuit chip. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The methods as discussed above are used in the fabrication of integrated circuit chips.

The resulting integrated circuit chips can be distributed by the fabricator in raw wafer form (that is, as a single wafer that has multiple unpackaged chips), as a bare chip, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products (such as, but not limited to, an information processing system) having a display, a keyboard, or other input device, and a central processor.

As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention.

The terms “a” or “an”, as used herein, are defined as one as or more than one. The term plurality, as used herein, is defined as two as or more than two. Plural and singular terms are the same unless expressly stated otherwise. The term another, as used herein, is defined as at least a second or more. The terms including and/or having, as used herein, are defined as comprising (i.e., open language). The term coupled, as used herein, is defined as connected, although not necessarily directly, and not necessarily mechanically. The terms program, software application, and the like as used herein, are defined as a sequence of instructions designed for execution on a computer system. A program, computer program, or software application may include a subroutine, a function, a procedure, an object method, an object implementation, an executable application, an applet, a servlet, a source code, an object code, a shared library/dynamic load library and/or other sequence of instructions designed for execution on a computer system.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

What is claimed is:

1. A carbon-based semiconductor device, the carbon-based semiconductor device comprising:
a substrate;
source and drain contacts formed on the substrate;
a graphene channel formed on the substrate connecting the source contact and the drain contact;
a dielectric layer formed on the graphene channel with a molecular beam deposition process; and
a gate contact formed over the graphene channel and on the dielectric, wherein the gate contact is in a non-overlapping position with the source and drain contacts leaving exposed sections of the graphene channel between the gate contact and the source and drain contacts.

2. The carbon-based semiconductor device of claim 1, wherein the dielectric layer comprises one of lanthanum oxide and lanthanum aluminate.

3. The carbon-based semiconductor device of claim 1, wherein the dielectric layer is formed one of at 25° C. and below 25° C.

4. The carbon-based semiconductor device of claim 1, wherein the dielectric layer is formed over the graphene channel, the source and drain contacts and the substrate.

5. The carbon-based semiconductor device of claim 1, wherein the exposed sections of the graphene channel are doped with an n-type or p-type dopant.

6. The carbon-based semiconductor device of claim 1, further comprising:
one or more graphene layers formed on the substrate.

7. The carbon-based semiconductor device of claim 6, wherein the substrate comprises a wafer having an insulating overlayer and wherein the graphene layers are formed by depositing the graphene layers on a surface of the insulating overlayer using exfoliation.

8. The carbon-based semiconductor device of claim 6, wherein the substrate comprises a silicon carbide wafer and wherein the graphene layers are formed by growing the graphene layers on the silicon carbide wafer by silicon sublimation with epitaxy.

9. The carbon-based semiconductor device of claim 6, wherein the source and drain contacts are formed on the substrate by:
patterning a resist mask over the graphene layers and the substrate to define source and drain contact regions; and
depositing a metal around the resist mask in the source and drain contact regions to form the source and drain contacts; and removing the resist mask.

10. The carbon-based semiconductor device of claim 6, wherein the graphene channel is formed on the substrate by:
patterning a mask on the graphene layers to define an active channel region;
removing portions of the graphene layers unprotected by the mask; and
removing the mask.

11. A non-transitory tangible computer readable medium encoded with a program for fabricating an integrated circuit structure, the program comprising instructions configured to:
provide a substrate;
form source and drain contacts on the substrate;
form a graphene channel on the substrate connecting the source contact and the drain contact;
form a dielectric layer on the graphene channel with a molecular beam deposition process; and
form a gate contact over the graphene channel and on the dielectric, wherein the gate contact is in a non-overlapping position with the source and drain contacts leaving exposed sections of the graphene channel between the gate contact and the source and drain contacts.

12. The non-transitory tangible computer readable medium of claim 11, wherein the dielectric layer comprises one of lanthanum oxide and lanthanum aluminate.

13. The non-transitory tangible computer readable medium of claim 11, wherein the dielectric layer is formed one of at 25 ° C. and below 25 ° C.

14. The non-transitory tangible computer readable medium of claim 11, wherein the instructions are further configured to: form the dielectric layer over the graphene channel, the source and drain contacts and the substrate.

15. The non-transitory tangible computer readable medium of claim 11, wherein the instructions are further configured to:
dope the exposed sections of the graphene channel with an n-type or p-type dopant.

16. The non-transitory tangible computer readable medium of claim 11, wherein the instructions are further configured to:
form one or more graphene layers on the substrate.

17. The non-transitory tangible computer readable medium of claim 16, wherein the substrate comprises a wafer having an insulating overlayer and wherein the graphene layers are formed by:
depositing the graphene layers on a surface of the insulating overlayer using exfoliation.

18. The non-transitory tangible computer readable medium of claim 16, wherein the substrate comprises a silicon carbide wafer and wherein the graphene layers are formed by:
growing the graphene layers on the silicon carbide wafer by silicon sublimation with epitaxy.

19. The non-transitory tangible computer readable medium of claim 16, wherein the instructions are further configured to form the source and drain contacts on the substrate by:
patterning a resist mask over the graphene layers and the substrate to define source and drain contact regions; and
depositing a metal around the resist mask in the source and drain contact regions to form the source and drain contacts; and removing the resist mask.

20. The non-transitory tangible computer readable medium of claim 16, wherein the instructions are further configured to form the graphene channel on the substrate by:
patterning a mask on the graphene layers to define an active channel region;
removing portions of the graphene layers unprotected by the mask; and
removing the mask.
